(19) United States
(12) Patent Application Publication
(10) Pub. No.: US 2006/0150906 A1
(43) Pub. Date: Jul. 13, 2006

(54) Wafer boat for reduced shadow marks

(76) Inventor: Louis J. M. Selen, Eindhoven (NL)

Correspondence Address: KNOBBE MARTENS OLSON & BEAR LLP, 2040 MAIN STREET, FOURTEENTH FLOOR, IRVINE, CA, 92614, US

(21) Appl. No.: 11/031,530

(22) Filed: Jan. 7, 2005

(51) Int. Cl. C23C 16/00

(52) U.S. Cl. 118/715; 118/728; 427/248.1

(57) ABSTRACT

Wafer boats include three or more boat rods having recesses ground into them to support wafers. Recess heights are increased relative to conventional boats in order to reduce shadow marks in layers deposited by chemical vapor deposition (CVD) employing BTBAS or other CVD processes that are particularly sensitive to shadow effects from the support recesses.

### FIELD OF THE INVENTION

The invention relates to semiconductor wafer processing and more in particular to wafer boats to hold a plurality of semiconductor wafers during thermal processing.

### BACKGROUND AND SUMMARY OF THE INVENTION

Vertical furnaces are common processing apparatuses for the thermal processing of semiconductor wafers. During processing the wafers are accommodated in a wafer boat in a vertically stacked, spaced relationship. In the most common and simple boat design, as shown in FIG. 1, the wafer boat is indicated in its entirety by reference numeral 1. Three or more vertically oriented rods 2, 3 and 4 are each attached at an upper and lower end, respectively, to a top plate 5 and a bottom plate 6. In the rods vertically spaced recesses 10 are formed at corresponding heights, the remaining material forming wafer support ridges. Corresponding recesses at the same height in each of the rods collectively form an accommodation for a wafer wherein the wafer is supported at an edge region thereof by the wafer support ridges. Although this boat design is simple and straightforward, and adequate for many process conditions, in a number of process conditions the boat rods cause shadowing effects on the wafer. Several processes are particularly sensitive for this shadowing effect. Such sensitive processes include oxide deposition using POCl₃ and O₂ at atmospheric pressure and film deposition using Low Pressure Chemical Vapor Deposition (LPCVD). LPCVD processes in which gas phase reactions play an important role, such as LPCVD of silicon oxide films using Tetra-Ethyl-Ortho-Silicate (TEOS) and LPCVD of silicon oxide using silane and N₂O, have been found especially sensitive to this shadowing effect. More recently it has appeared that is also inflicted with this shadowing effect.

Although several solutions have been proposed in the prior art, such as employing point support of a wafer, or wafer holder rings supported by the boat, such designs are complicated and costly.

It is an object of the present invention to provide a simpler wafer boat that avoids the disadvantage of shadowing effects.

In accordance with one aspect of the invention, a vertical batch reactor for chemical vapor deposition is provided. The reactor includes a process tube, a plurality of reactant gas sources in selective fluid communication with the process tube, and a wafer boat configured to accommodate a plurality of vertically spaced wafers. The wafer boat includes three or more boat rods having vertically spaced recesses each having a vertical height. The rods are arranged with respect to one another to accommodate a plurality of wafers of a specified diameter, where a ratio of the vertical height of the recess to the specified diameter is between about 0.020 and 0.050.

In accordance with another aspect of the invention, a method for processing wafers in a vertical reactor is provided. The method includes loading a plurality of wafers into a wafer boat. The wafer boat includes a plurality of boat rods having a plurality of recesses formed therein. The recesses are separated by support ridges, wherein a thickness of each ridge plus a height of a ridge recess defines a pitch size. The height of each recess represents at least 60% of the pitch size. The method also includes inserting the wafer boat with the wafers into a vertical process tube and depositing a layer by chemical vapor deposition on the plurality of wafers within the process tube.

In accordance with another aspect of the invention, a wafer boat for vertical batch processing is provided. The boat includes three or more boat rods, each boat rod having a plurality of recesses separated by similar support ridges. Each recess extends vertically from a top surface of a first support ridge to a lower surface of a second support ridge and is further defined by a recess outer wall connecting the top surface of the first support ridge to the lower surface of the second support ridge. A pitch of the wafer boat is defined by the sum of a height of each recess and a thickness of each support ridge, wherein the height of each recess represents between about 65% and 85% of the pitch.

### BRIEF DESCRIPTION OF THE DRAWING

These and other aspects of the invention will be readily appreciated from the preferred embodiments described below and from the appended drawings, which are meant to illustrate and not to limit the invention, and wherein:

FIG. 1 is a perspective view of a prior art wafer boat;

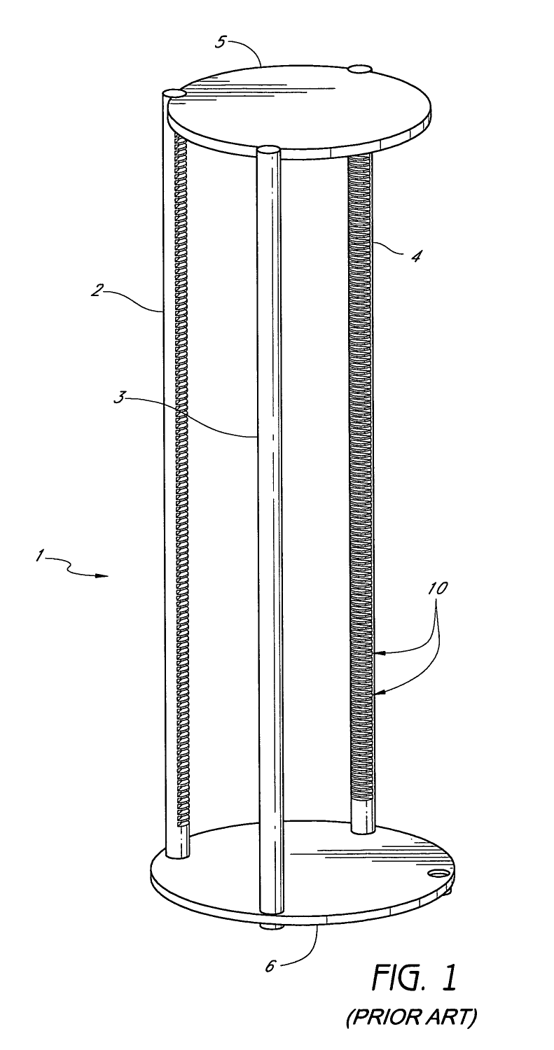

FIG. 2 is a schematic cross section of a boat rod, showing shows the characteristic dimensions of recesses in a boat rod.

FIG. 3 is a schematic overhead view of a wafer supported by three rods of a wafer boat.

FIG. 4A is a schematical cross section of a conventional boat rod, shown with wafers loaded into only every other slot;

FIG. 4B is a schematic cross section of a boat rod according to preferred embodiments of the present invention;

FIG. 5 is a schematic view of a vertical furnace reactor configured for chemical vapor deposition of silicon nitride using BTBAS as a precursor, in accordance with preferred embodiments of the present invention.

### DETAILED DESCRIPTION OF THE PREFERRED EMBODIMENTS

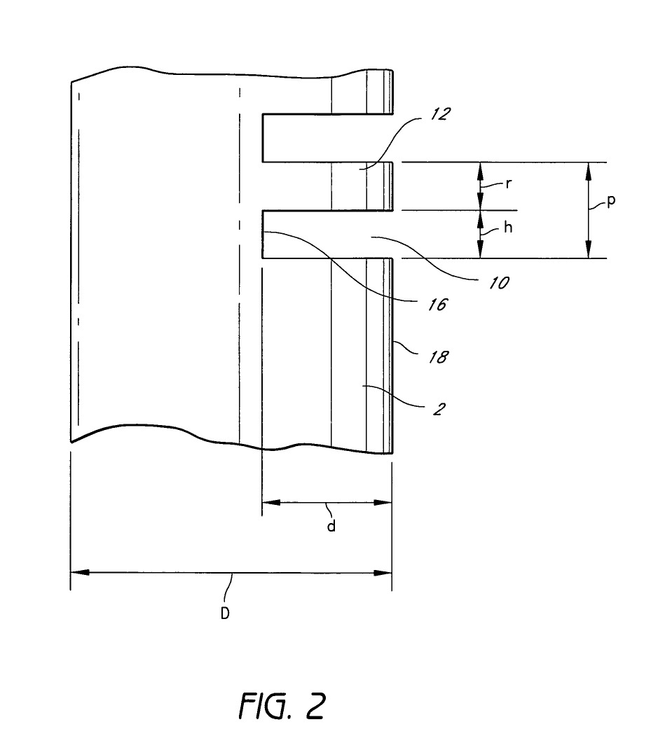

FIG. 2 shows the characteristic dimensions of recesses in a wafer boat. In FIG. 2, the boat rod indicated by 2, the recess by 10 and the wafer support ridge by 12. The height of the recess 10 is h, the height of the wafer support ridge 12 is r, and the wafer pitch is p, where p=h+r. The depth of the recess is d, extending from a recess outer wall 16 to an inner surface 18 of the rod 2, and the diameter of the rod 2 is D.

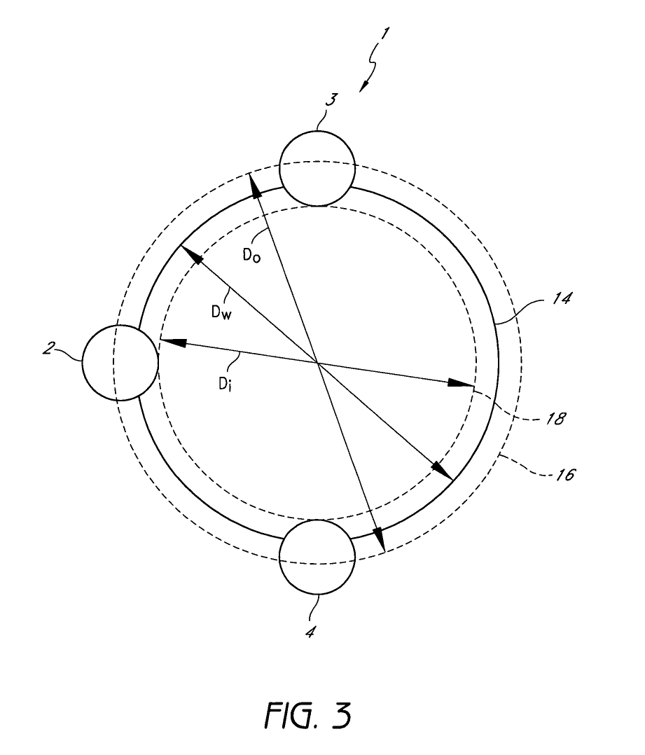

FIG. 3 is an overhead view schematically illustrating the relative size of the wafer 14 and the features that define the recesses 10 (FIG. 2) of the rods 2, 3, 4. The sizes of the rods 2, 3, 4 are exaggerated for purposes of illustrating the difference in diameter of the circles defined by the wafer 14, the outer walls 16 of the recesses 10, and the inner surfaces 18 of the rods 2, 3, 4. In FIG. 3, the diameter of the inner surfaces 18 of the rods is indicated by Dᵢ, the diameter of the wafer 14 is indicated by D_{w} and the diameter of the outer wall 16 of the recesses 10 is indicated by Dₒ. As will be appreciated by the skilled artisan, the wafer boat 1 is generally designed to accommodate a wafer 14 of specific diameter. Thus, a 200-mm wafer boat 14 has rods 2, 3, 4 positioned and configured with the inner surfaces 18 of the rods defining a circle with diameter Dᵢ of less than 200 mm, while the outer walls 16 of the recesses 10 define a circle of diameter Dₒ of greater than 200 mm. Thus, the ridges 12 (FIG. 2) extend beneath and support the wafer, while the recesses 10 (FIG. 2) are deep enough to accommodate the wafer. Similarly, a 300-mm wafer boat 14 is configured with rods 2, 3, 4 positioned and designed with the rod inner surfaces 18 defining a circle of diameter Dᵢ of less than 300 mm while the outer walls 16 of the recesses 10 define a circle of diameter Dₒ of greater than 300 mm.

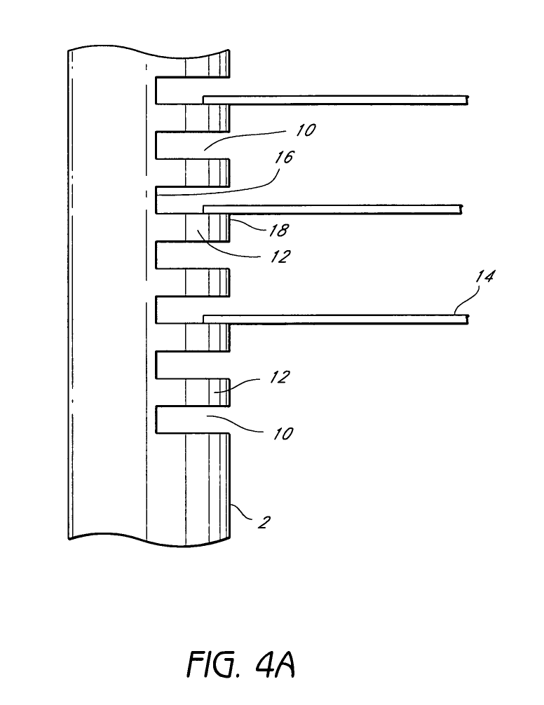

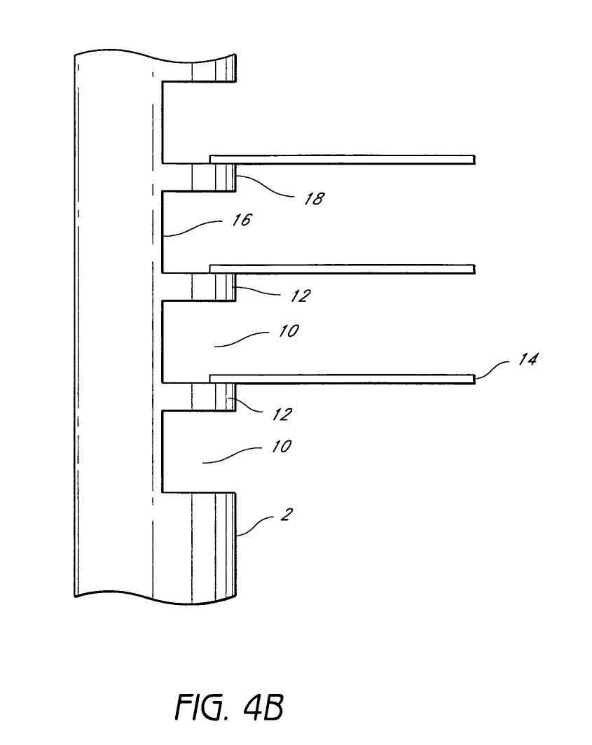

FIG. 4A shows a vertical cross-section of a boat rod design according to the prior art. Recesses 10 are formed in the boat rod 2 so that edge portions of a wafer 14 can be supported on the wafer support ridges 12. Most economically, the rods are formed as straight, solid elongated elements, and the recesses 10 are formed by removing material from the boat rod 2, such as by grinding. The simplicity of the design requires only one recess 10 per wafer slot in each rod 2, 3, 4.

Typically, the recesses 10 are high enough to accommodate the thickness of the wafer and to allow some vertical movement during placement and retrieval of the wafer. A further increase of the recess height in the boat rod 2 of FIG. 4A would require the additional removal of material, which adds to the costs of the grinding process. Increasing the height of the recesses without changing the pitch would also result in a reduced thickness of the remaining wafer support ridges 12 in between the recesses 10, on which the wafers 14 are supported, and thus in reduced strength and durability of the boat, which is undesirable. Furthermore, increasing the height of the recesses without reducing the thickness of the ridges 12 would decrease the number of wafers that could be accommodated within the boat 1 for a given boat height. Typical boat dimensions for a 200 mm wafer boat and a 300 mm wafer boat are given in the left two columns of Table I, below (‘Standard boat, single pitch’). The positioning of the rods and the dimensioning of the recesses are such that the distance between the wafer edge and vertical wall 16 of the recess is about 1.5 mm for both the 200 mm and 300 mm wafer boats, and the overlap area between the wafer and the support ridge extends about 5 mm inwardly from the edge of the wafer 14. To accommodate dimension variation in the boat manufacturing, and to avoid the risk of wafers fall out of the wafer accommodations of the boat, a much smaller overlap is not desirable. It will be clear that variations around the given values can be applied.

In standard processes, like wet or dry oxidation at atmospheric pressure, or LPCVD of polysilicon films, the wafers can be stacked close together having a wafer pitch of about 4.173 mm for 200 mm wafers and 7.635 mm for 300 mm wafers. However, it has been found that certain processes require a larger pitch to obtain a desirable uniformity in film thickness or doping level over the wafer. Among these processes are LPCVD of nitride films using Bis-Tertiary-Butyl-Amino-Silane (BTBAS), LPCVD of silicon oxide films using Tetra-Ethyl-Ortho-Silicate (TEOS), and LPCVD of silicon oxide using silane and N₂O. Other processes wherein the process uniformity improves with increased pitch are atmospheric processes for the deposition of phosphorus-doped oxide films using POCl₃, or other atmospheric gas phase doping processes.

Preferably, these processes are operated at double wafer pitch, as is shown in FIG. 4A. In that case a wafer is loaded into every other wafer accommodation in the wafer boat. In the LPCVD BTBAS experiments that resulted in the present invention, the film thickness uniformity within improved significantly when a double pitch was applied. Nevertheless, boat rod shadow effects were still observed.

It was found that these shadow effects disappeared when every other support ridge was ground away, as is shown in FIG. 4B wherein similar parts are provided with the same reference numerals as in FIG. 4A. This resulted in a significantly increased free height above the wafer. As indicated in the right two columns of Table I, the recess height of the preferred boat represents 60-85% of the pitch, as the recess height is increased while the ridge thickness has been maintained. With an adequate recess height, the proximity of the boat rod material above the wafer edges has no strong influence anymore. The within wafer film uniformity of the LPCVD BTBAS process improved from a I sigma value of about 2% and a maximum-minimum value of about 7% (the maximum thickness of the deposited layer being 7% greater than the minimum thickness of the layer) to respectively a 1 sigma value below 1% and a maximum-minimum value of about 2%.

TABLE I

| | | | Standard boat, single | | Improved boat, double | |
|---|---|---|---|---|---|---|
| | Unit | Symbol | pitch | | pitch | |
| Wafer diameter | mm | D_{w} | 200 | 300 | 200 | 300 |
| Pitch | mm | P | 4.173 | 7.635 | 8.346 | 15.27 |
| Recess height | mm | h | 2.3 | 4 | 6.47 | 11.64 |
| Recess height (% of | % | 100ₕ | 55 | 52 | 78 | 76 |
| pitch) | | p | | | | |
| Support ridge height | mm | r | 1.873 | 3.635 | 1.873 | 3.635 |
| Rod diameter | mm | D | 19 | 22 | 19 | 22 |
| Slot depth | mm | d | 6.5 | 6.5 | 6.5 | 6.5 |
| Recess height: wafer | | h:D_{w} | 0.0115 | 0.01333 | 0.03235 | 0.0388 |
| diameter | | | | | | |
| Pitch: wafer diameter | | p:D_{w} | 0.0209 | 0.02545 | 0.04173 | 0.0509 |

It will be clear that another value for the pitch can be selected, e.g. a pitch that is 1.5 times larger than the standard pitch, rather than double. This will result in a larger load size of wafers. Alternatively, for very sensitive processes an even larger pitch than double pitch might be required. For a 200-mm wafer boat recess height to avoid boat rod shadow marks is preferably larger than 5 mm, more preferably larger than 6 mm. For a 300-mm wafer boat the recess height is preferably larger than 6 mm, more preferably larger than 7 mm. In an alternative design, the recess height should be as high as possible without affecting the strength of the support ridges. The support ridge should be at least 1.5 mm in thickness for a 200-mm wafer boat and at least 2 mm for a 300 mm wafer boat to be sufficiently robust.

More generally, the ratio of recess height to wafer diameter (h:D_{w}) is preferably between about 0.020 and 0.050, and more preferably between about 0.030 and 0.045 in order to minimize the shadow effect while maximizing stacking density (and thus throughput). The ratio of pitch to wafer diameter (p:D_{w}) is preferably between about 0.030 and 0.070 and more preferably between about 0.035 and 0.060 in order to minimize shadow effect while maximizing throughput. The recess height is preferably at least 60% of the pitch, and more preferably at least 70% of the pitch.

Like the conventional design of FIG. 4A, but unlike more complicated boat designs configured for supporting wafers and support rings during processing, the boat 1 of FIG. 4B includes a simple repeating pattern for supporting wafers, consisting of a support ridge 12 and a recess 10. The recess 10 is thus defined by an upper surface of one support ridge 12, the recess outer wall 16 and the lower surface of an identical overlying support ridge 12. This simple repeating pattern ensures low manufacturing costs.

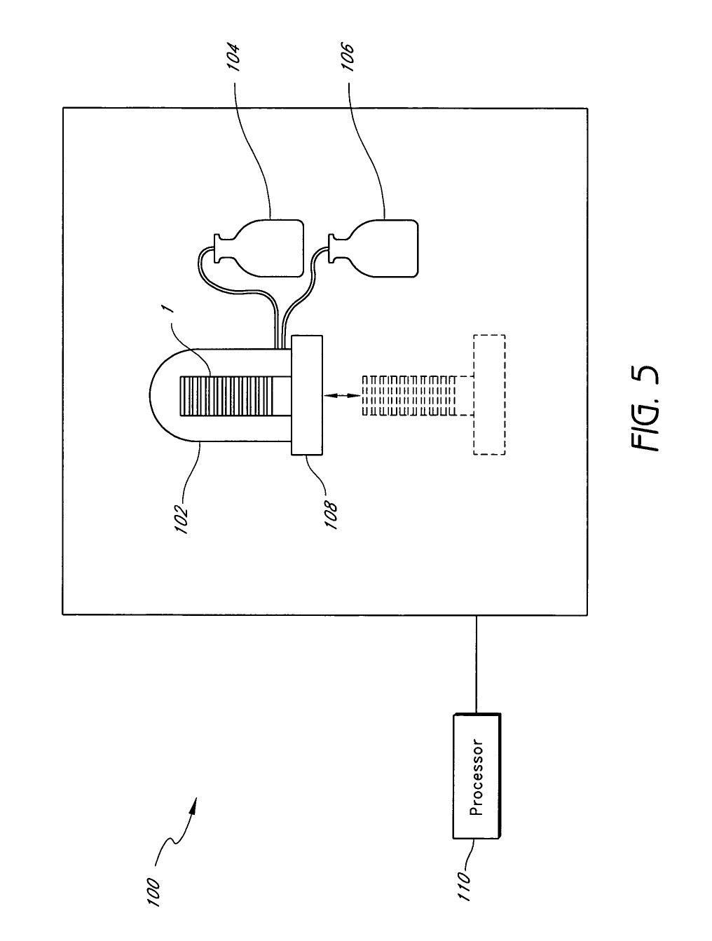

FIG. 5 schematically illustrates the system in which the boat 1 of the preferred embodiment, with an increased recess height, is employed. As shown, the boat 1 is positioned within a reactor 100. The reactor 100 includes a process tube 102, which is connected to a plurality of process gas sources 104, 106. Preferably, the gases are chosen to be suitable for LPCVD of silicon oxide film using TEOS; an LPCVD of silicon oxide using silane and N₂O; deposition of phosphorous-doped silicon oxide films using POCl₃; or most preferably for LPCVD of silicon nitride films using BTBAS. The boat 1 is positioned upon a door plate 108 that can be elevated from a lower load position (shown in phantom lines in FIG. 5) into the upper process position within the process tube 102. A processor 110, such as a computer including memory and programs for conducting processing steps, such as robotic loading of the boat 1 upon the door plate 108, lifting the door plate 108, and controlling heaters and gas supply in a manner to effect CVD, is included within the reactor 100.

In processing, a plurality of wafers are loaded into the wafer boat 1. The boat is then loaded upon the door plate 108. In alternative arrangements the boat can remain permanently mounted on the door plate and the loading of wafers is conducted while the door plate is in the lowered position. After loading, the wafer boat 1 is lifted into the process tube 102 where the wafers are heated for CVD processing. When temperatures have stabilized, process gases are provided into the process tube 102 and deposition is conducted.

It will be appreciated by those skilled in the art that various omissions, additions, and modifications may be made to the methods and structures described above without departing from the scope of the invention. All such modifications and changes are intended to fall within the scope of the invention, as defined by the appended claims.

I claim:

1. A vertical batch reactor for chemical vapor deposition, comprising:
a process tube;
a plurality of reactant gas sources in selective fluid communication with the process tube; and
a wafer boat configured to accommodate a plurality of vertically spaced wafers, the wafer boat comprising three or more boat rods having vertically spaced recesses each having a vertical height, the rods arranged with respect to one another to accommodate a plurality of wafers of a specified diameter, wherein a ratio of the vertical height of the recesses to the specified diameter of the wafers is between about 0.020 and 0.050.

2. The reactor of claim 1, wherein the specified diameter is 200 mm and the vertical height of the recesses is 5 mm or greater.

3. The reactor of claim 2, wherein the vertical height of the recesses is 6 mm or greater.

4. The reactor of claim 1, wherein the specified diameter is 300 mm, and the vertical height of the recesses is 6 mm or more.

5. The reactor of claim 4, wherein the vertical height of the recesses is 7 mm or more.

6. The reactor of claim 1, wherein the gas sources include a source of bis-tertiary-butyl-amino-silane (BTBAS).

7. The reactor of claim 1, wherein the gas sources include a source of tetra-ethyl-ortho-silicate (TEOS).

8. The method of claim 1, wherein the gas sources include a source of POCl₃.

9. The reactor of claim 1, wherein the vertical height of the recesses to the specified diameter of the wafers is between about 0.030 and 0.045.

10. A method of processing wafers in a vertical reactor, the method comprising:
loading a plurality of wafers into a wafer boat, the wafer boat comprising a plurality of boat rods having a plurality of recesses formed therein, the recesses separated by support ridges, wherein a thickness of each ridge plus a height of each recess defines a pitch size, and the height of each recess represents at least 60 % of the pitch size;
inserting the wafer boat with the wafers into a vertical process tube; and
depositing a layer by chemical vapor deposition on the plurality of wafers within the process tube.

11. The method of claim 10, wherein depositing comprises a process selected from the group consisting of:
low pressure chemical vapor deposition (LPCVD) of silicon nitride films using bis-tertiary-butyl-amino-silane (BTBAS);
LPCVD of silicon oxide using tetra-ethyl-ortho-silicate (TEOS);
LPCVD of silicon oxide using silane and N₂O; and
an atmospheric process for depositing phosphorous doped silicon oxide films using POCl₃.

12. The method of claim 10, wherein depositing comprises low pressure chemical vapor deposition (LPCVD) of silicon nitride films using bis-tertiary-butyl-amino-silane (BTBAS).

13. The method of claim 10, wherein the height of each recess is at least 70% of the pitch size.

14. The method of claim 10, wherein the wafer boat is configured to accommodate 200-mm wafers, and the height of each recess is about 5 mm or greater.

15. The method of claim 14, wherein the height of each recess is about 6 mm or greater.

16. The method of claim 10, wherein the wafer boat is configured to accommodate 300-mm wafers, and the height of each recess is about 6 mm or greater.

17. The method of claim 16, wherein the vertical height of the recesses is about 7 mm or greater.

18. A wafer boat for vertical batch processing, the boat comprising three or more boat rods, each boat rod having a plurality of recesses separated by similar support ridges, each recess extending vertically from a top surface of a first support ridge to a lower surface of a second support ridge and further defined by a recess outer wall connecting the top surface of the first support ridge to the lower surface of the second support ridge, a pitch of the wafer boat being defined by the sum of a height of each recess and a thickness of each support ridge, wherein the height of each recess represents between about 60% and 85% of the pitch.

19. The wafer boat of claim 18, wherein the height of the recess represents greater than 70% of the pitch.

20. The wafer boat of claim 18, wherein a ratio of the pitch to a diameter of a wafer for which the boat is configured to support is between about 0.035 and 0.060.

21. The wafer boat of claim 18, configured to accommodate 200-nm wafers, wherein the height of each recess is about 5 mm or greater.

22. The wafer boat of claim 21, wherein the height of each recess is about 6 mm or greater.

23. The wafer boat of claim 18, configured to accommodate 300-mm wafers, wherein the height of each recess is about 6 mm or greater.

24. The wafer boat of claim 23, wherein the height of each recess is about 7 mm or greater.
